(19) United States
(12) Patent Application Publication
(10) Pub. No.: US 2022/0159884 A1
(43) Pub. Date: May 19, 2022

(54) RADIO WAVE ABSORBER AND KIT FOR RADIO WAVE ABSORBER

(71) Applicant: NITTO DENKO CORPORATION, Ibaraki-shi, Osaka (JP)

(72) Inventors: Kazuhiro Fuke, Osaka (JP); Masatsugu Koso, Osaka (JP); Yuya Matsuzaki, Osaka (JP)

(73) Assignee: NITTO DENKO CORPORATION, Ibaraki-shi, Osaka (JP)

(21) Appl. No.: 17/438,536

(22) PCT Filed: Mar. 6, 2020
(86) PCT No.: PCT/JP2020/009802

§ 371 Date: Sep. 13, 2021

(30) Foreign Application Priority Data
Mar. 15, 2019 (JP) 2019-048835

(51) Int. Cl. H05K 9/00

(52) U.S. Cl. CPC H05K 9/0081

(57) ABSTRACT

A radio wave absorber includes a first radio wave absorbing portion and a second radio wave absorbing portion. The first radio wave absorbing portion has the largest amount of reflection and absorption, as measured according to JIS R 1679: 2007, of a radio wave with a given frequency f at a first incident angle θ₁ in an incident angle range of 0° to 80°. The second radio wave absorbing portion has the largest amount of reflection and absorption of the radio wave at a second incident angle θ₂ in an incident angle range of 0° to 80°. Magnitude of the second incident angle θ₂ is different from magnitude of the first incident angle θ₁, or a polarized wave type of the radio wave incident at the second incident angle θ₂ is different from a polarized wave type of the radio wave incident at the first incident angle θ₁.

### TECHNICAL FIELD

The present invention relates to a radio wave absorber and a kit for a radio wave absorber.

### BACKGROUND ART

Radio wave absorbers that exhibit predetermined absorption performance for a radio wave incident at a wide range of incident angles or a variety of polarized waves have been under consideration.

For example, Patent Literature 1 describes a radio wave absorber including a reflective layer having a surface where at least one of a protruding part and a depression part is distributed and an absorption layer laminated along the surface of the reflective layer. On the surface of the reflective layer, the absorption layer is arranged at a constant thickness along a surface contour of the reflective layer.

### CITATION LIST

### Patent Literature

Patent Literature 1: JP 2004-207506 A

### SUMMARY OF INVENTION

### Technical Problem

According to the technique described in Patent Literature 1, at least one of the protruding part and the depression part needs to be distributed on the surface of the reflective layer, and the absorption layer needs to be arranged at a constant thickness along the surface contour of the reflective layer.

In view of such circumstances, the present invention provides a radio wave absorber advantageous in terms of exhibiting desired absorption performance for a radio wave incident at a wide range of incident angles or a variety of polarized waves with neither a protruding part nor a depression part arranged on a surface of an electrical conductor that reflects a radio wave. The present invention also provides a kit for a radio wave absorber, the kit being advantageous in terms of configuring such a radio wave absorber.

### Solution to Problem

The present invention provides a radio wave absorber including:

a first radio wave absorbing portion having the largest amount of reflection and absorption, as measured according to Japanese Industrial Standards (JIS) R 1679: 2007, of a radio wave with a given frequency at a first incident angle in an incident angle range of 0° to 80°; and

a second radio wave absorbing portion having the largest amount of reflection and absorption of the radio wave at a second incident angle in an incident angle range of 0° to 80°, wherein

magnitude of the second incident angle is different from magnitude of the first incident angle, or a polarized wave type of the radio wave incident at the second incident angle is different from a polarized wave type of the radio wave incident at the first incident angle, and

the first radio wave absorbing portion and the second radio wave absorbing portion are disposed along a given surface.

The present invention also provides a kit for a radio wave absorber, including:

a first piece for forming a first radio wave absorbing portion having the largest amount of reflection and absorption, as measured according to JIS R 1679: 2007, of a radio wave with a given frequency at a first incident angle in an incident angle range of 0° to 80°; and

a second piece for forming a second radio wave absorbing portion having the largest amount of reflection and absorption of the radio wave at a second incident angle in an incident angle range of 0° to 80°, wherein

magnitude of the second incident angle is different from magnitude of the first incident angle, or a polarized wave type of the radio wave incident at the second incident angle is different from a polarized wave type of the radio wave incident at the first incident angle.

### Advantageous Effects of Invention

The above radio wave absorber is advantageous in terms of exhibiting desired absorption performance for a radio wave incident at a wide range of incident angles or a variety of polarized waves with neither a protruding part nor a depression part arranged on a surface of an electrical conductor that reflects a radio wave.

### BRIEF DESCRIPTION OF DRAWINGS

FIG. 1A is a plan view showing an example of a radio wave absorber according to the present invention.

FIG. 1B is a cross-sectional view of the radio wave absorber along an IB-IB line shown in FIG. 1A.

FIG. 2 is a cross-sectional view showing an example of a kit for a radio wave absorber according to the present invention.

FIG. 3 is a plan view showing another example of the kit for a radio wave absorber according to the present invention.

FIG. 4 shows another example of the radio wave absorber according to the present invention.

FIG. 5 shows yet another example of the radio wave absorber according to the present invention.

### DESCRIPTION OF EMBODIMENTS

Embodiments of the present invention will be described with reference to the drawings. The present invention is not limited to the following embodiments.

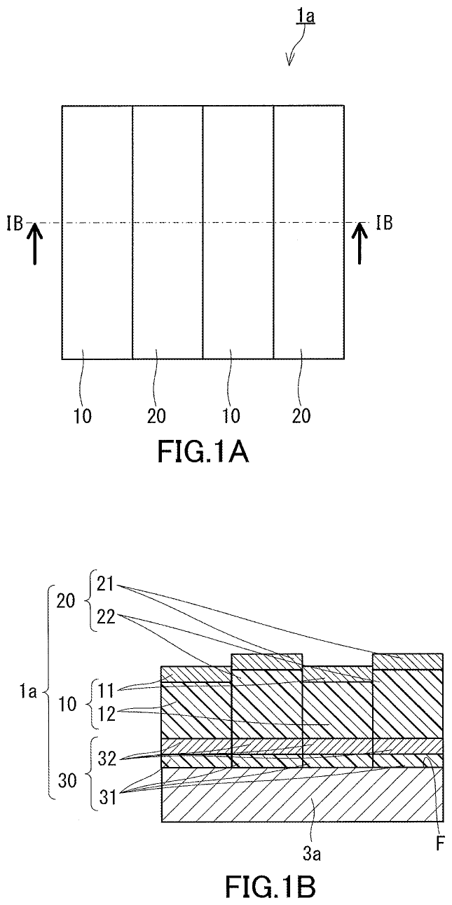

As shown in FIGS. 1A and 1B, a radio wave absorber 1a includes a first radio wave absorbing portion 10 and a second radio wave absorbing portion 20. The first radio wave absorbing portion 10 has the largest amount of reflection and absorption, as measured according to JIS R 1679: 2007, of a radio wave with a given frequency f at a first incident angle θ₁ in an incident angle range of 0° to 80°. The term “amount of reflection and absorption” is synonymous with, for example, the absolute value of a return loss S (dB) defined by the following formula (1). In the formula (1). P₀ is received power (W/m²) obtained from reflection by a metal plate, and P₁ is received power (W/m²) obtained from reflection by a specimen. Additionally, the amount of reflection and absorption corresponds to the absolute value of the amount of reflection as in JIS R 1679: 2007. The second radio wave absorbing portion 20 has the largest amount of reflection and absorption, as measured according to JIS R 1679: 2007, of the radio wave with the given frequency f at a second incident angle θ₂ in an incident angle range of 0° to 80°. Magnitude of the second incident angle θ₂ is different from magnitude of the first incident angle θ₁, or a polarized wave type of the radio wave incident at the second incident angle θ₂ is different from a polarized wave type of the radio wave incident at the first incident angle θ₁. In the radio wave absorber 1a, the first radio wave absorbing portion 10 and the second radio wave absorbing portion 20 are disposed along a given surface F. The given surface F may be a flat surface, a curved surface, an uneven surface, or a surface with a corner. For the radio wave absorbing portions, the amount of reflection and absorption of the radio wave with the frequency f is measured, for example, using a specimen whose planar shape is a 200 mm² square. That is, the term “amount of reflection and absorption of a radio wave” as used herein refers to a value of the amount of reflection and absorption determined when the radio wave absorbing portions are configured to have the planar shape of a 200 mm² square.

$$S = 10 log \vert \frac{{P}_{i}}{{P}_{0}} \vert \qquad ( 1 )$$

The radio wave absorber 1a is likely to have a wide range of incident angles at which desired absorption performance is exhibited, or exhibits desired absorption performance for different types of polarized waves. Moreover, in the radio wave absorber 1a, neither a protruding part nor a depression part may be arranged on a surface of an electrical conductor that reflects a radio wave.

The frequency f of a radio wave that can be absorbed by the radio wave absorber 1a is not limited to a particular frequency. An obliquely incident radio wave that can be absorbed by the radio wave absorber 1a may be a TM wave or a TE wave.

In the radio wave absorber 1a, when the polarized wave type of the radio wave incident at the second incident angle θ₂ is the same as the polarized wave type of the radio wave incident at the first incident angle θ₁ or the first incident angle θ₁ is 0°, a value determined by subtracting the first incident angle θ₁ from the second incident angle θ₂ is, for example, 5° or more. In this case, the range of incident angles at which the radio wave absorber 1a exhibits desired absorption performance is likely to be wide.

When the polarized wave type of the radio wave incident at the second incident angle θ₂ is the same as the polarized wave type of the radio wave incident at the first incident angle θ₁ or the first incident angle θ₁ is 0°, the value determined by subtracting the first incident angle θ₁ from the second incident angle θ₂ may be 10° or more, 30° or more, or 50° or more.

When the polarized wave type of the radio wave incident at the second incident angle θ₂ is the same as the polarized wave type of the radio wave incident at the first incident angle θ₁ or the first incident angle θ₁ is 0°, the value determined by subtracting the first incident angle θ₁ from the second incident angle θ₂ is, for example, 70° or less. In this case, the range of incident angles at which the radio wave absorber 1a exhibits desired absorption performance is likely to be wide.

When the polarized wave type of the radio wave incident at the second incident angle θ₂ is the same as the polarized wave type of the radio wave incident at the first incident angle θ₁ or the first incident angle θ₁ is 0°, the value determined by subtracting the first incident angle θ₁ from the second incident angle θ₂ may be 65° or less, 45° or less, or 25° or less.

In the radio wave absorber 1a, a range R₁₅ of incident angles at which the amount of reflection and absorption of, for example, a TM wave is 15 dB or more is 35° or more. As this indicates, the radio wave absorber 1a is likely to exhibit desired absorption performance, for example, for a radio wave incident at a wide range of incident angles. The range R₁₅ is desirably 40° or more and more desirably 45° or more. It should be noted that, for the radio wave absorber 1a, for example, R₁₅=(θ_{b}−θₐ)+(θ_{d}−θ_{c}) is satisfied if the relationship θ₁≤θₐ<θ_{b}<θ_{c}<θ_{d}≤θ₂ is satisfied and the amount of reflection and absorption is 15 dB or more at incident angles in the ranges of θₐ≤θ≤θ_{b} and θ_{c}≤θ≤θ_{d} and less than 15 dB at incident angles in the range of θ_{b}<θ<θ_{c}.

In the radio wave absorber 1a, a range R₁₀ of incident angles at which the amount of reflection and absorption of, for example, a TE wave is 10 dB or more is 30° or more. As this indicates, the radio wave absorber 1a is likely to exhibit desired absorption performance, for example, for a radio wave incident at a wide range of incident angles. The range R₁₀ is desirably 35° or more and more desirably 40° or more. It should be noted that, for the radio wave absorber 1a, for example, R₁₀=(θ_{b}−θₐ)+(θₐ−θ_{c}) is satisfied if the relationship θ₁≤θₐ<θ_{b}<θ_{c}<θ_{d}≤θ₂ is satisfied and the amount of reflection and absorption is 10 dB or more at incident angles in the ranges of θₐ≤θ≤θ_{b} and θ_{c}≤θ≤θ_{d} and less than 10 dB at incident angles in the range of θ_{b}<θ<θ_{c}.

In the radio wave absorber 1a, a ratio S₂/S₁ of an area S₂ of a portion where the given surface F is covered by the second radio wave absorbing portion 20 to an area S₁ of a portion where the given surface F is covered by the first radio wave absorbing portion 10 is, for example, 1/10 to 10. In this case, the radio wave absorber 1a can more reliably exhibit desired absorption performance for a radio wave incident at a wide range of angles or a variety of polarized waves.

S₂/S₁ may be ⅛ or more, ¼ or more, or ½ or more. S₂/S₁ may be 8 or less, 4 or less, or 2 or less.

As shown in FIGS. 1A and 1B, the radio wave absorber 1a includes, for example, a plurality of the first radio wave absorbing portions 10 and a plurality of the second radio wave absorbing portions 20. The plurality of first radio wave absorbing portions 10 and the plurality of second radio wave absorbing portions 20 are disposed regularly or randomly along the given surface F. When a specimen for measurement of the amount of reflection and absorption of a radio wave with the frequency f cannot be configured to have the above-described size and planar shape using only one first radio wave absorbing portion 10, a specimen for measurement of the amount of reflection and absorption of a radio wave with the frequency f is produced using the plurality of first radio wave absorbing portions 10. The same applies to the case where a specimen for measurement of the amount of reflection and absorption of a radio wave with the frequency f cannot be configured to have the above-described size and planar shape using only one second radio wave absorbing portion 20.

As shown in FIG. 1A, the plurality of first radio wave absorbing portions 10 and the plurality of second radio wave absorbing portions 20 are disposed, for example, alternately along the given surface F. In this case, the radio wave absorber 1a is less likely to have spatially uneven absorption performance for a radio wave incident at a wide range of angles or a variety of polarized waves.

In the radio wave absorber 1a, the first radio wave absorbing portions 10 may be adjacent to each other, or the plurality of second radio wave absorbing portions 20 may be disposed between the first radio wave absorbing portions 10. In the radio wave absorber 1a, the second radio wave absorbing portions 20 may be adjacent to each other, or the plurality of first radio wave absorbing portions 10 may be disposed between the second radio wave absorbing portions 20.

When the radio wave absorber 1a is viewed toward the given surface F in the direction perpendicular to the given surface F, the planar shapes of the first radio wave absorbing portion 10 and the second radio wave absorbing portion 20 are not limited to a particular shape. The outlines of the planar shapes may be formed of straight lines, curved lines, or a combination of straight and curved lines.

As shown in FIG. 1B, the radio wave absorber 1a is, for example, attached to an adherend 3a. The adherend 3a has the given surface F.

The first radio wave absorbing portion 10 and the second radio wave absorbing portion 20 are, for example, configured based on any of the following non-reflection condition formulae (2) to (4). The formula (2) is a non-reflection condition formula for a perpendicularly incident radio wave. The formula (3) is a non-reflection condition formula for a TE wave. The formula (4) is a non-reflection condition formula for a TM wave. In the formulae (2) to (4), λ is the wavelength of a radio wave to be absorbed, d is the thickness of an absorbing material, and θ is the incident angle of the radio wave.

$$1 = \sqrt{\frac{{\dot{μ}}_{r}}{{\dot{ɛ}}_{r}}} tanh ( j \frac{2 π d}{λ} \sqrt{{\dot{ɛ}}_{r} {\dot{μ}}_{r}} ) \qquad ( 2 )$$

In the formula (2), \dot{μ}ᵣ is the complex magnetic permeability of the absorbing material, and \dot{ε}ᵣ is the complex permittivity of the absorber.

$$\begin{matrix}1 = \frac{{\dot{μ}}_{r} cos θ}{\sqrt{{\dot{ɛ}}_{r} {\dot{μ}}_{r} - {sin}^{2} θ}} tanh ( j \frac{2 π d}{λ} \sqrt{{\dot{ɛ}}_{r} {\dot{μ}}_{r} - {sin}^{2} θ} ) & ( 3 ) \\ 1 = \frac{\sqrt{{\dot{ɛ}}_{r} {\dot{μ}}_{r} - {sin}^{2} θ}}{{\dot{ɛ}}_{r} cos θ} tanh ( j \frac{2 π d}{λ} \sqrt{{\dot{ɛ}}_{r} {\dot{μ}}_{r} - {sin}^{2} θ} ) & ( 4 )\end{matrix}$$

As shown in FIG. 1B, the first radio wave absorbing portion 10 includes, for example, a first resistive layer 11 and a first dielectric layer 12. The first dielectric layer 12 is disposed between the first resistive layer 11 and the given surface F in a thickness direction of the first resistive layer 11. Additionally, the second radio wave absorbing portion 20 includes, for example, a second resistive layer 21 and a second dielectric layer 22. The second dielectric layer 22 is disposed between the second resistive layer 21 and the given surface F in a thickness direction of the second resistive layer 21. In other words, the radio wave absorber 1a is a λ/4 radio wave absorber. The first radio wave absorbing portion 10 and the second radio wave absorbing portion 20 each typically have a surface that reflects a radio wave and that is made of an electrical conductor. The radio wave absorber 1a is designed to cause interference between a radio wave reflected by a surface of the first resistive layer 11 or the second resistive layer 21 (front surface reflection) and a radio wave reflected by the electrical conductor (back surface reflection) upon incidence of a radio wave having a wavelength λ to be absorbed on the radio wave absorber 1a. The sheet resistance of the first resistive layer 11 and that of the second resistive layer 21 are determined so that an impedance expected on a front surface of each of the first resistive layer 11 and the second resistive layer 21 will be equal to a characteristic impedance of a plane wave based on the transmission-line theory. The radio wave absorber 1a may be a radio wave absorber including a dielectric loss material and a magnetic loss material.

As shown in FIG. 1B, the radio wave absorber 1a further includes, for example, a connecting layer 30. The connecting layer 30 is disposed closer to the given surface F than the first dielectric layer 12 is in a thickness direction of the first dielectric layer 12 and disposed closer to the given surface F than the second dielectric layer 22 is in a thickness direction of the second dielectric layer 22. The connecting layer 30 connects, for example, the first dielectric layer 12 and the second dielectric layer 22 to the given surface F.

The connecting layer 30 includes, for example, an adhesive layer 31. In this case, the radio wave absorber 1a can be disposed at a given position. The adhesive layer 31 may be formed of separated portions each corresponding to the first radio wave absorbing portion 10 or the second radio wave absorbing portion 20 or may be formed as an inseparable one in the radio wave absorber 1a. The adhesive layer 31 is, for example, in contact with the given surface F. The adhesive layer includes, for example, a rubber adhesive, an acrylic adhesive, a silicone adhesive, or a urethane adhesive.

The connecting layer 30 includes, for example, an electrically conductive layer 32 and the adhesive layer 31. The electrically conductive layer 32 reflects a radio wave to be absorbed (back surface reflection). The electrically conductive layer 32 may be formed of separated portions each corresponding to the first radio wave absorbing portion 10 or the second radio wave absorbing portion 20 or may be formed as an inseparable one in the radio wave absorber 1a. The adhesive layer 31 is disposed, for example, between the electrically conductive layer 32 and the given surface F in the thickness direction of the electrically conductive layer 32. The adhesive layer 31 is, for example, in contact with the given surface F.

The electrically conductive layer 32 is, for example, a metallic foil or an alloy foil. The electrically conductive layer 32 may be a metal plate. The electrically conductive layer 32 may be formed, for example, by forming an electrical conductor film on a substrate by a method such as sputtering, ion plating, plating, or coating (for example, bar coating). The electrically conductive layer 32 may be formed by rolling.

A ratio r₂/r₁ of a sheet resistance r₂ of the second resistive layer 21 to a sheet resistance r₁ of the first resistive layer 11 is, for example, 0.001 to 100. In this case, the range of incident angles at which the radio wave absorber 1a exhibits desired absorption performance is likely to be wide.

The ratio r₂/r₁ may be 0.04 or more, 0.08 or more, or 0.2 or more. The ratio r₂/r₁ may be 30 or less, 12 or less, or 5 or less. Typically, r₂/r₁<1 is satisfied when a radio wave to be absorbed includes a TM wave, and r₂/r₁>1 is satisfied when a radio wave to be absorbed includes a TE wave.

In the radio wave absorber 1a, a ratio D₂/D₁ of a thickness D₂ of the second dielectric layer 12 to a thickness D₁ of the first dielectric layer 11 is, for example, 0.01 to 10. The ratio D₂/D₁ in this range is likely to lead to a wider variety of incidence conditions, such as incident angles, under which the radio wave absorber 1a exhibits desired absorption performance. The relative permittivity of the first dielectric layer 11 and that of the second dielectric layer 12 are, for example, relative permittivities measured at 10 GHz by a cavity resonance method.

The ratio D₂/D₁ may be 0.1 or more, 0.2 or more, or 0.3 or more. The ratio D₂/D₁ may be 7 or less, 5 or less, or 3 or less.

The materials of the first resistive layer 11 and the second resistive layer 21 are not limited to a particular material as long as they have desired sheet resistances. Examples of the materials of the first resistive layer 11 and the second resistive layer 21 include indium tin oxide (ITO). In this case, the sheet resistance of the first resistive layer 11 and that of the second resistive layer 21 are easily adjusted in desirable ranges.

The first dielectric layer 12 and the second dielectric layer 22 are each formed of, for example, a given polymer. The first dielectric layer 12 and the second dielectric layer 22 each include, for example, at least one polymer selected from the group consisting of ethylene-vinyl acetate copolymer, vinyl chloride resin, urethane resin, acrylic resin, acrylic urethane resin, polyethylene, polypropylene, silicone, polyethylene terephthalate, polyethylene naphthalate, polycarbonate, polyimide, and cycloolefin polymer. In this case, the thickness of the first dielectric layer 12 and that of the second dielectric layer 22 are easily adjusted and the manufacturing cost of the radio wave absorber 1a can be maintained at a low level. The first dielectric layer 12 and the second dielectric layer 22 can be produced by shaping a given resin composition, for example, by hot pressing.

The first dielectric layer 12 and the second dielectric layer 22 each may be formed as a single layer or as a plurality of layers made of the same material or different materials. When the first dielectric layer 12 and the second dielectric layer 22 each include n layers (n is an integer of 2 or greater), the relative permittivity of the first dielectric layer 12 and that of the second dielectric layer 22 are each determined, for example, as follows. The relative permittivity εᵢ of each layer is measured (i is an integer of 1 to n). Then, the relative permittivity εᵢ of each layer is multiplied by the proportion of the thickness tᵢ of the layer to the total thickness T of the first dielectric layer 12 or the second dielectric layer 22 to determine εᵢ×(tᵢ/T). The relative permittivity of the dielectric layer can be determined by adding the εᵢ×(tᵢ/T) values of all layers thereof.

When the first dielectric layer 12 has a plurality of layers, the first dielectric layer 12 may include a substrate serving as a support supporting the first resistive layer 11. Moreover, the first dielectric layer 12 may include a substrate serving as a support supporting the electrically conductive layer 32. When the second dielectric layer 22 has a plurality of layers, the second dielectric layer 22 may include a substrate serving as a support supporting the second resistive layer 21. Moreover, the second dielectric layer 12 may include a substrate serving as a support supporting the electrically conductive layer 32. Examples of the materials of these substrates include polyethylene terephthalate (PET), polyethylene naphthalate (PEN), acrylic resin (PMMA), polycarbonate (PC), polyimide (PI), and cycloolefin polymer (COP). In particular, the materials of the substrates are desirably PET in terms of the balance between good heat resistance, the dimensional stability, and the manufacturing cost.

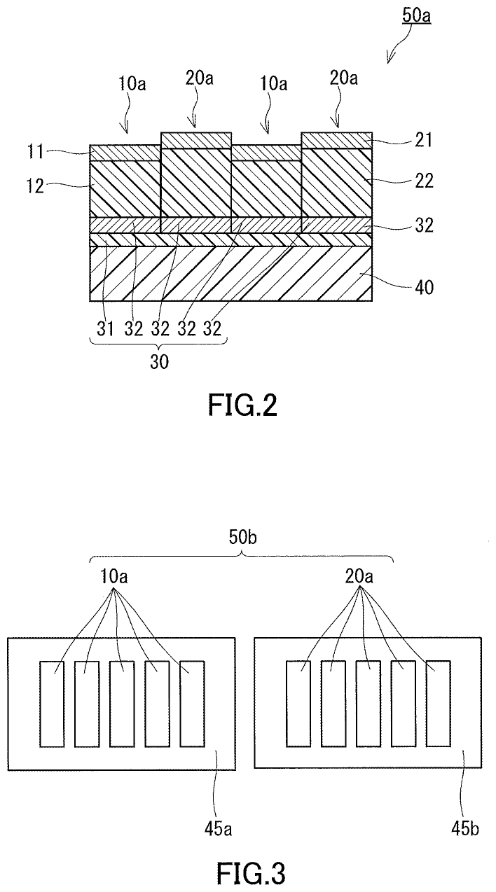

The radio wave absorber 1a is produced, for example, using a given kit for a radio wave absorber. As shown in FIG. 2, a kit 50a for a radio wave absorber includes a first piece 10a and a second piece 20a. The first piece 10a is a piece for forming the first radio wave absorbing portion 10. The second piece 20a is a piece for forming the second radio wave absorbing portion 20.

The kit 50a for a radio wave absorber includes, for example, a substrate 40. In the kit 50a for a radio wave absorber, the first piece 10a is disposed to cover a portion of the substrate 40. The second piece 20a is disposed to cover another portion of the substrate 40. The first piece 10a and the second piece 20a are fixed on the substrate 40, for example, by the adhesive layer 31. The substrate 40 can be peeled off from the adhesive layer 31. Accordingly, the radio wave absorber 1a can be produced by peeling off the substrate 40 from the adhesive layer 31 to bare the adhesive layer 31 and then pressing the adhesive layer 31 against the given surface F of the adherend 3a. The substrate 40 is, for example, a film made of a polyester resin such as PET.

The radio wave absorber 1a may be produced using a kit 50b, as shown in FIG. 3, for a radio wave absorber. The kit 50b for a radio wave absorber includes, for example, the first piece 10a, the second piece 20a, a first substrate 45a, and a second substrate 45b. The first piece 10a is disposed on the first substrate 45a, and the second piece 20a is disposed on the second substrate 45b. The first piece 10a is fixed on the first substrate 45a, for example, by the adhesive layer 31. The first substrate 45a can be peeled off from the first piece 10a. The second piece 20a is fixed on the second substrate 45b, for example, by the adhesive layer 31. The second substrate 45b can be peeled off from the second piece 20a. For example, the first piece 10a and the second piece 20a are respectively detached from the first substrate 45a and the second substrate 45b and are then disposed along the given surface F of the adherend 3a. The first piece 10a and the second piece 20a are subsequently pressed against the given surface F. The radio wave absorber 1a can thus be produced.

The radio wave absorber 1a can be modified in various respects. The radio wave absorber 1a includes one or more types of radio wave absorbing portions. The radio wave absorber 1a may further include, for example, a third radio wave absorbing portion. In this case, the third radio wave absorbing portion is disposed along the given surface F together with the first radio wave absorbing portion 10 and the second radio wave absorbing portion 20. The third radio wave absorbing portion has different properties from those of the first radio wave absorbing portion 10 and the second radio wave absorbing portion 20 in terms of the amount of reflection and absorption, as measured according to JIS R 1679: 2007, of a radio wave with the given frequency f. For example, the third radio wave absorbing portion has the largest amount of reflection and absorption of a radio wave with the given frequency f at a third incident angle θ₃ in the incident angle range of 0° to 80°. The third incident angle θ₃ is, for example, different from the first incident angle θ₁ and the second incident angle θ₂. Alternatively, the polarized wave type of a radio wave incident at the third incident angle θ₃ is different from the polarized wave type of a radio wave incident at the first incident angle θ₁ or the polarized wave type of a radio wave incident at the second incident angle θ₁. For example, it is assumed that the second radio wave absorbing portion 20 has the largest amount of reflection and absorption of a radio wave that is a TM wave with the given frequency f at the second incident angle θ₂ (0°<θ₂≤80°). In this case, the radio wave absorber 1a may further include the third radio wave absorbing portion, and the third radio wave absorbing portion may have the largest amount of reflection and absorption of a radio wave that is a TE wave with the given frequency f at the third incident angle θ₃ (0°<θ₃≤80°).

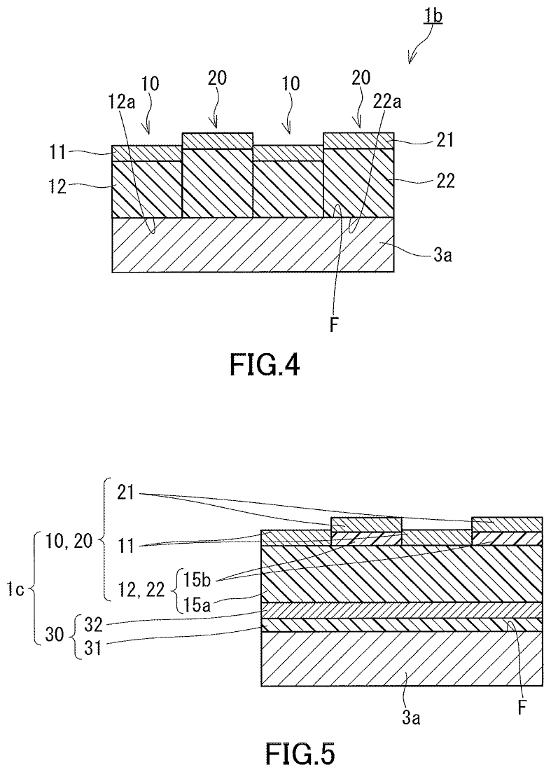

The radio wave absorber 1a may be modified to radio wave absorbers 1b and 1c respectively shown in FIGS. 4 and 5. The radio wave absorbers 1b and 1c are configured in the same manner as the radio wave absorber 1a unless otherwise described. The components of the radio wave absorbers 1b and 1c that are the same as or correspond to the components of the radio wave absorber 1a are denoted by the same reference characters, and detailed descriptions of such components are omitted. The description given for the radio wave absorber 1a is applicable to the radio wave absorbers 1b and 1c unless there is a technical inconsistency.

In the radio wave absorber 1b, the given surface F of the adherend 3a is formed of an electrical conductor. Therefore, a radio wave can be reflected by the given surface F of the adherend 3a (back surface reflection). The first dielectric layer 12 includes, for example, a first adhesive surface 12a, and the first adhesive surface 12a is in contact with the given surface F. The second dielectric layer 22 includes, for example, a second adhesive surface 22a, and the second adhesive surface 22a is in contact with the given surface F. The first adhesive surface 12a may be formed of the first dielectric layer 12 or may be formed of an adhesive layer. The second adhesive surface 22a may be formed of the second dielectric layer 22 or may be formed of an adhesive layer.

As shown in FIG. 5, the radio wave absorber 1c includes a shared dielectric layer 15a and an unshared dielectric layer 15b. The shared dielectric layer 15a has a constant thickness along the given surface F and is a portion shared by the first dielectric layer 12 and the second dielectric layer 22. The unshared dielectric layer 15b is placed on a portion of the shared dielectric layer 15a, the portion corresponding to the second radio wave absorbing portion 20. In other words, the first dielectric layer 12 is formed only of the shared dielectric layer 15a while the second dielectric layer 22 is formed of a section where the shared dielectric layer 15a and the unshared dielectric layer 15b are laminated. In the radio wave absorber 1c, the connecting layer 30 is formed as an inseparable one.

An exemplary method for producing the radio wave absorber 1c will be described. For example, the connecting layer 30 and the shared dielectric layer 15a are stacked. Then, the unshared dielectric layer 15b is placed on the shared dielectric layer 15a in a section constituting the second radio wave absorbing portion 20. Next, the first resistive layer 11 is placed on the shared dielectric layer 15a in a section constituting the first radio wave absorbing portion 10. Moreover, the second resistive layer 21 is placed on the unshared dielectric layer 15b in the section constituting the second radio wave absorbing portion 20. The radio wave absorber 1c can thus be produced.

In the radio wave absorber 1c, the first dielectric layer 12 and the second dielectric layer 22 are composed of the shared dielectric layer 15a and the unshared dielectric layer 15b. Alternatively, it is also possible to compose the first dielectric layer 12 and the second dielectric layer 22 only of the shared dielectric layer 15a. In this case, for example, the shared dielectric layer 15a is produced so that the shared dielectric layer 15a in the section constituting the first radio wave absorbing portion 10 and the shared dielectric layer 15a in the section constituting the second radio wave absorbing portion 20 will have different thicknesses.

### EXAMPLES

Hereinafter, the present invention will be described in more detail by examples. The present invention is not limited to the examples given below.

### Example 1

A resistive layer A having a thickness of 55 nm and a sheet resistance of 370Ω/□ was formed on a 23-μm-thick PET film by sputtering using ITO as a target material. A resistive layer-attached film A was thus obtained. An acrylic resin having a relative permittivity of 2.6 was shaped to a thickness of 560 μm to obtain an acrylic resin layer A. The resistive layer-attached film A was placed on the acrylic resin layer A in such a manner that the resistive layer A of the resistive layer attached film A was in contact with the acrylic resin layer A. The resistive layer attached film A was adhered to the acrylic resin layer A without using an adhesive. A piece A was thus obtained. The planar shape of the piece A was a rectangle having a length of 200 mm and a width of 100 mm.

A resistive layer B having a thickness of 110 nm and a sheet resistance of 160Ω/□ was formed on a 23-μm-thick PET film by sputtering using ITO as a target material. A resistive layer-attached film B was thus obtained. An acrylic resin having a relative permittivity of 2.6 was shaped to a thickness of 710 μm to obtain an acrylic resin layer B. The resistive layer-attached film B was placed on the acrylic resin layer B in such a manner that the resistive layer B of the resistive layer-attached film B was in contact with the acrylic resin layer B. The resistive layer attached film B was adhered to the acrylic resin layer B without using an adhesive. A piece B was thus obtained. The planar shape of the piece B was a rectangle having a length of 200 mm and a width of 100 mm.

An electrical conductor-including film K was prepared in which a 7-μm-thick aluminum foil is sandwiched between a 25-μm-thick PET film and a 9-μm-thick PET film and the aluminum foil and the PET films are laminated. The planar shape of the electrical conductor-including film K was a 200 mm² square. The piece A was placed in such a manner that the acrylic resin layer A was in contact with the electrical conductor-including film K. The piece B was also placed in such a manner that the acrylic resin layer B was in contact with the electrical conductor-including film K. The one piece A and the one piece B were thus placed on the electrical conductor-including film K Consequently, the electrical conductor-including film K was covered by the pieces A and B. A sample according to Example 1 was thus obtained. The acrylic resin layers A and B were adhered to the electrical conductor including film K without using an adhesive.

### Example 2

Pieces A and B were cut to a width of 67 mm. The piece A was placed in such a manner that the acrylic resin layer A was in contact with an electrical conductor including film K The piece B was also placed in such a manner that the acrylic resin layer B was in contact with the electrical conductor-including film K.

Consequently, the electrical conductor-including film K was covered by the pieces A and B. A sample according to Example 2 was thus obtained. The acrylic resin layers A and B were adhered to the electrical conductor-including film K without using an adhesive.

### Example 3

A resistive layer C having a thickness of 17 nm and a sheet resistance of 930Ω/□ was formed on a 23-μm-thick PET film by sputtering using ITO as a target material. A resistive layer-attached film C was thus obtained. An acrylic resin having a relative permittivity of 2.6 was shaped to a thickness of 660 μm to obtain an acrylic resin layer C. The resistive layer-attached film C was placed on the acrylic resin layer C in such a manner that the resistive layer C of the resistive layer-attached film C was in contact with the acrylic resin layer C. The resistive layer attached film C was adhered to the acrylic resin layer C without using an adhesive. A piece C was thus obtained. The planar shape of the piece C was a rectangle having a length of 200 mm and a width of 100 mm.

Apiece A was placed in such a manner that the acrylic resin layer A was in contact with an electrical conductor-including film K. The piece C was also placed in such a manner that the acrylic resin layer B was in contact with the electrical conductor-including film K Consequently, the electrical conductor-including film K was covered by the pieces A and C. A sample according to Example 3 was thus obtained. The acrylic resin layers A and C were adhered to the electrical conductor-including film K without using an adhesive.

### Comparative Example 1

Two pieces A were placed on an electrical conductor-including film K in such a manner that the acrylic resin layers A were in contact with the electrical conductor-including film K Consequently, the electrical conductor-including film K was covered by the pieces A. A sample according to Comparative Example 1 was thus obtained. The acrylic resin layers A were adhered to the electrical conductor including film K without using an adhesive.

### Comparative Example 2

Two pieces B were placed on an electrical conductor-including film K in such a manner that the acrylic resin layers B were in contact with the electrical conductor-including film K Consequently, the electrical conductor-including film K was covered by the pieces B. A sample according to Comparative Example 2 was thus obtained. The acrylic resin layers B were adhered to the electrical conductor including film K without using an adhesive.

### Comparative Example 3

Two pieces C were placed on an electrical conductor-including film K in such a manner that the acrylic resin layers C were in contact with the electrical conductor-including film K. Consequently, the electrical conductor-including film K was covered by the pieces C. A sample according to Comparative Example 3 was thus obtained. The acrylic resin layers C were adhered to the electrical conductor including film K without using an adhesive.

[Measurement of Absorption Amount]

The samples according to Examples and Comparative Examples were each measured for an absorption amount (the absolute value of the ratio, expressed in dB, of the electric power of a reflected wave to the electric power of an incident wave) according to JIS R 1679: 2007 using a 76-GHz millimeter wave incident on each sample at an incident angle of 0° to 70°. The measurement was performed at incident angles of 0°, 15°, 30°, 45°, 60°, and 70°. TM and TE waves were used as obliquely incident radio waves in the measurement of the absorption amounts of the sample according to Comparative Example 1. A TM wave was used as an obliquely incident radio wave in the measurement of the absorption amounts of the samples according to Examples 1 to 3 and Comparative Example 2. A TE wave was used as an obliquely incident radio wave in the measurement of the absorption amounts of the samples according to Example 4 and Comparative Example 3. The major axis of an irradiated spot on each sample irradiated by the TM and TE waves extended in the length direction of the pieces at the center of the surface of each sample. From the results for the absorption amount measurement for the samples according to Examples 1 to 3 and Comparative Examples 1 and 2 using a TM wave, the range R₁₅ of incident angles at which the absorption amount is 15 dB or more was identified for each sample. The range R₁₅ was identified based on the method, described in DESCRIPTION OF EMBODIMENTS, for determining the range R₁₅. The results are shown in Table 1. Meanwhile, from the results for the absorption amount measurement for the samples according to Example 4 and Comparative Examples 1 and 3 using a TE wave, the range R₁₀ of incident angles at which the absorption amount is 10 dB or more was identified for each sample. The range R₁₀ was identified based on the method, described in DESCRIPTION OF EMBODIMENTS, for determining the range R₁₀. The results are shown in Table 1. The sample according to Comparative Example 1 had the largest absorption amount at an incident angle of 0°. The samples according to Comparative Examples 2 and 3 had the largest absorption amount at an incident angle of 70°.

As shown in Table 1, the ranges R₁₅ of the samples according to Examples 1 and 2 were greater than the ranges R₁₅ of the samples according to Comparative Examples 1 and 2. Additionally, the range R₁₀ of the sample according to Example 3 was greater than the ranges R₁₀ of the samples according to Comparative Examples 1 and 3. These indicate that the samples according to Examples 1 to 3 have wider ranges of incident angles at which desired radio wave absorption performance is exhibited.

TABLE 1

| | | Ratio of sheet | | | |
|---|---|---|---|---|---|
| | | resistance r_{b} or r_{c} of | | | |
| | | resistive layer B or C | Ratio of area S_{b} or | Radio wave absorption | |
| | | to sheet resistance rₐ | S_{c} of piece B or C to | performance | |
| | Type of | of resistive layer A | area Sₐ of piece A | TM wave | TE wave |
| | pieces used | (r_{b}/rₐ or r_{c}/rₐ) | (S_{b}/Sₐ or S_{c}/Sₐ) | R₁₅ [°] | R₁₀ [°] |
| Example 1 | A and B | 0.43 | 1 | More than | — |
| | | | | 60° | |
| Example 2 | A and B | 0.43 | 1/2 | More than | — |
| | | | | 45° | |
| Example 3 | A and C | 2.51 | 1 | — | More than |
| | | | | | 40° |
| Comparative | Only A | — | — | More than | More than |
| Example 1 | | | | 30° and less | 30° and less |
| | | | | than 45° | than 40° |
| Comparative | Only B | — | — | More than | — |
| Example 2 | | | | 10° and less | |
| | | | | than 25° | |
| Comparative | Only C | — | — | — | More than |
| Example 3 | | | | | 25° and less |
| | | | | | than 40° |

1. A radio wave absorber comprising:
a first radio wave absorbing portion having the largest amount of reflection and absorption, as measured according to Japanese Industrial Standards (JIS) R 1679: 2007, of a radio wave with a given frequency at a first incident angle in an incident angle range of 0° to 80°; and
a second radio wave absorbing portion having the largest amount of reflection and absorption of the radio wave at a second incident angle in an incident angle range of 0° to 80°, wherein
magnitude of the second incident angle is different from magnitude of the first incident angle, or a polarized wave type of the radio wave incident at the second incident angle is different from a polarized wave type of the radio wave incident at the first incident angle, and
the first radio wave absorbing portion and the second radio wave absorbing portion are disposed along a given surface.

2. The radio wave absorber according to claim 1, wherein
the polarized wave type of the radio wave incident at the second incident angle is the same as the polarized wave type of the radio wave incident at the first incident angle, or the first incident angle is 0°, and
a value determined by subtracting the first incident angle from the second incident angle is 5° or more.

3. The radio wave absorber according to claim 1, wherein
the polarized wave type of the radio wave incident at the second incident angle is the same as the polarized wave type of the radio wave incident at the first incident angle, or the first incident angle is 0°, and
a value determined by subtracting the first incident angle from the second incident angle is 70° or less.

4. The radio wave absorber according to claim 1, wherein a ratio of an area of a portion where the given surface is covered by the second radio wave absorbing portion to an area of a portion where the given surface is covered by the first radio wave absorbing portion is 1/10 to 10.

5. The radio wave absorber according to claim 1, comprising a plurality of the first radio wave absorbing portions and a plurality of the second radio wave absorbing portions, wherein
the plurality of first radio wave absorbing portions and the plurality of second radio wave absorbing portions are disposed regularly or randomly along the given surface.

6. The radio wave absorber according to claim 5, wherein the plurality of first radio wave absorbing portions and the plurality of second radio wave absorbing portions are disposed alternately along the given surface.

7. The radio wave absorber according to claim 1, wherein
the first radio wave absorbing portion comprises a first resistive layer and a first dielectric layer disposed between the first resistive layer and the given surface in a thickness direction of the first resistive layer, and
the second radio wave absorbing portion comprises a second resistive layer and a second dielectric layer disposed between the second resistive layer and the given surface in a thickness direction of the second resistive layer.

8. The radio wave absorber according to claim 7, further comprising a connecting layer disposed closer to the given surface than the first dielectric layer is in a thickness direction of the first dielectric layer and disposed closer to the given surface than the second dielectric layer is in a thickness direction of the second dielectric layer.

9. The radio wave absorber according to claim 8, wherein the connecting layer comprises an adhesive layer.

10. The radio wave absorber according to claim 8, wherein the connecting layer comprises an electrically conductive layer and an adhesive layer.

11. The radio wave absorber according to claim 7, wherein a ratio of a sheet resistance of the second resistive layer to a sheet resistance of the first resistive layer is 0.001 to 100.

12. The radio wave absorber according to claim 7, wherein a ratio of a thickness of the second dielectric layer to a thickness of the first dielectric layer is 0.01 to 10.

13. A kit for a radio wave absorber, comprising:
a first piece for forming a first radio wave absorbing portion having the largest amount of reflection and absorption, as measured according to JIS R 1679: 2007, of a radio wave with a given frequency at a first incident angle in an incident angle range of 0° to 80°; and
a second piece for forming a second radio wave absorbing portion having the largest amount of reflection and absorption of the radio wave at a second incident angle in an incident angle range of 0° to 80°, wherein
magnitude of the second incident angle is different from magnitude of the first incident angle, or a polarized wave type of the radio wave incident at the second incident angle is different from a polarized wave type of the radio wave incident at the first incident angle.
